(19) United States
(12) Patent Application Publication
(10) Pub. No.: US 2010/0302891 A1
(43) Pub. Date: Dec. 2, 2010

(54) SEMICONDUCTOR DEVICE AND METHOD OF DRIVING THE SAME

(76) Inventor: Jong Hyun WANG, Chungcheongbuk-do (KR)

Correspondence Address: IP & T GROUP LLP, 7700 Little River Turnpike, Suite 207, Annandale, VA, 22003, US

(21) Appl. No.: 12/649,975

(22) Filed: Dec. 30, 2009

(30) Foreign Application Priority Data
May 29, 2009 (KR) 2009-0047817

(51) Int. Cl. G11C 5/14; H03L 7/00

(52) U.S. Cl. 365/226; 327/143

(57) ABSTRACT

A semiconductor device includes a power-up operation unit configured to perform a power-up operation in response to a power-up enable signal and to output a powered-up control signal, and configured to output a power-up completion signal after the power-up operation is completed, an internal circuit configured to operate in response to the powered-up control signal, and a power-up detection unit configured to output a power-up flag signal in response to the power-up completion signal.

### CROSS-REFERENCE TO RELATED APPLICATION

Priority to Korean patent application number 10-2009-0047817 filed on May 29, 2009, the entire disclosure of which is incorporated by reference herein, is claimed.

### BACKGROUND

Exemplary embodiments relate to a semiconductor device and a method of driving the same and, more particularly, to a semiconductor device and a method of driving the same, which are capable of preventing an excessive current from being wasted when a power-up operation is performed on the semiconductor device including stack-type memory chips.

With the high integration of semiconductor devices, a number of memory chips are implemented within one package. For example, 2, 4, or 8 memory chips can be implemented within a single package. Further, a number of pins may protrude outside of the package. The chips are electrically coupled to the pins through respective wires, and are configured to transfer operation signals.

FIG. 1 is a block diagram illustrating a known semiconductor device.

The semiconductor device 10 includes a number of first to n^{th} memory chips (where ‘n’ is a natural number). The memory chips can have the same structure. Thus, the first memory chip is described below as an example. The first memory chip is supplied with signals, including a power source voltage Vcc, a first chip enable signal CE1, and a control signal CTRL, and is configured to output output signals, including a first operation signal RB1. Further, I/O signals I/Os are inputted to or outputted from the first memory chip. Pads configured to transfer respective signals, including the power source voltage Vcc, are electrically coupled with different pins protruding outside of the semiconductor device 10 through respective wires. The power source voltage Vcc is supplied to the memory chips as a voltage source, and the chip enable signals CE1 to CEn (where ‘n’ is a natural number) are enabled when the respective memory chips are selected. A control signal CTRL is used to control each memory chip, and it can include, for example, an address latch enable signal ALE. Each of the operation signals RB1 to RBn is inactivated when a corresponding chip is operated, thus indicating that the corresponding chip is operating. The I/O signals I/Os include a number of input signals or a number of output signals. A number of signals other than the above-described signals are inputted to and outputted from the memory chip through the pins, but a description thereof is omitted for convenience.

In a known art, bad block information, chip configuration information, and repair column information about a memory chip are set using a fuse.

However, recently, with an increase in the degree of integration of semiconductor devices, a cell instead of a fuse is mainly used to set the bad block information, the chip configuration information, and the repair column information. The cell can be implemented using a contents address memory (hereinafter referred to as ‘CAM’) cell having a nonvolatile characteristic.

Meanwhile, a memory chip includes an internal circuit, including a memory cell array, peripheral circuits, and a CAM cell (or a fuse). To operate the internal circuit, a power-up operation for raising the voltage level of the power source voltage Vcc is performed. A number of memory chips are recently included in one package. If the power-up operations for a number of the memory chips are performed at the same time, an excessive current flows within a package.

If excessive current flows within the package as described above, the lifespan of the CAM cells can be reduced, and so information about the memory chips can be changed. Consequently, the reliability of the semiconductor device can be deteriorated.

### BRIEF SUMMARY

Exemplary embodiments relate to a semiconductor device equipped with stack-type memory chips and a method of driving the same, which are capable of preventing excessive current from flowing by sequentially performing power-up operations for the memory chips.

A semiconductor device according to an aspect of the present disclosure includes a power-up operation unit configured to perform a power-up operation in response to a power-up enable signal and to output a powered-up control signal and configured to output a power-up completion signal after the power-up operation is completed, an internal circuit configured to operate in response to the powered-up control signal, and a power-up detection unit configured to output a power-up flag signal in response to the power-up completion signal.

The power-up operation unit includes a terminal to which the power-up enable signal is supplied. The terminal is electrically coupled through a wire to a pin receiving the power-up enable signal, protruding outside of the semiconductor device.

The power-up enable signal is supplied to the power-up operation unit through a pin to which a power source voltage is supplied.

The power-up operation unit is configured to perform the power-up operation in response to the power-up enable signal of a high logic level and to output the powered-up control signal and is also configured to output the power-up completion signal of a high logic level when a voltage level of the powered-up control signal shifts to a low logic level after the power-up operation is completed.

The internal circuit includes a memory cell array and a peripheral circuit unit.

The power-up detection unit includes a power-up detection element coupled between a terminal to which a power source voltage is supplied and a terminal from which the power-up flag signal is outputted and configured to operate in response to the power-up completion signal. The power-up detection element is implemented using an NMOS transistor.

A semiconductor device according to another aspect of the present disclosure includes a number of memory chips, a power-up operation unit included in each of the memory chips and configured to perform a power-up operation on an internal circuit included in each of the memory chips in response to a power-up enable signal, and a power-up detection unit configured to output a power-up flag signal in response to a power-up completion signal outputted from the power-up operation unit. The power-up flag signal generated from the power-up detection unit of a first memory chip from among the memory chips is supplied as the power-up enable signal of a next memory chip from among the memory chips.

A semiconductor device according to yet another aspect of the present disclosure includes a number of memory chips included in one package and coupled to pins of the package through wires, a power-up operation unit included in each of the memory chips and configured to perform a power-up operation on an internal circuit included in each of the memory chips in response to a power-up enable signal, and a power-up detection unit configured to output a power-up flag signal in response to a power-up completion signal outputted from the power-up operation unit. The power-up flag signal generated from the power-up detection unit of a first memory chip from among the memory chips is supplied as the power-up enable signal of a next memory chip from among the memory chips.

The power-up operation is sequentially performed in order from the first memory chip to a last memory chip from among the memory chips.

The semiconductor device further includes wires configured to transfer the power-up flag signal outputted from each of the memory chips on which the power-up operation has been completed to the power-up enable signal of the next memory chip.

The wires comprise internal wires coupled between the memory chips, such that the wires are not coupled to the pins of the package.

An input terminal of the power-up operation unit included in the first memory chip from among the memory chips is coupled to one of the pins of the package.

A method of operating a semiconductor device including a number of memory chips according to another aspect of the present disclosure includes performing a power-up operation on a first memory chip of the memory chips, and performing the power-up operation on a next memory chip of the memory chips, after the power-up operation is completed. The power-up operation is sequentially performed up to a last memory chip of the memory chips.

While the power-up operation is performed on a selected memory chip of the memory chips, the power-up operation is not performed on remaining memory chips other than the selected memory chip.

### BRIEF DESCRIPTION OF THE DRAWINGS

FIG. 1 is a block diagram illustrating a known semiconductor device;

FIG. 2 is a block diagram illustrating any one of stack-type memory chips according to the present disclosure;

FIG. 3 is a circuit diagram of a power-up detection unit included in the memory chip;

FIG. 4 is a block diagram illustrating a semiconductor device, including a package according to the present disclosure; and

FIG. 5 is a block diagram illustrating a semiconductor device, including stack-type memory chips according to the present disclosure.

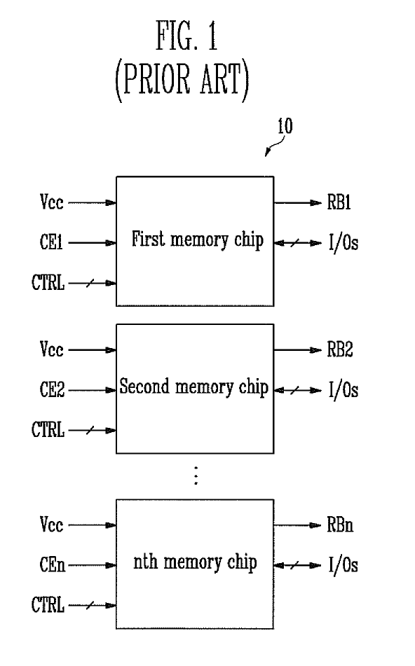

### DESCRIPTION OF EMBODIMENTS

Hereinafter, exemplary embodiments of the present disclosure will be described in detail with reference to the accompanying drawings. The figures are provided to allow those having ordinary skill in the art to understand the scope of the embodiments of the disclosure.

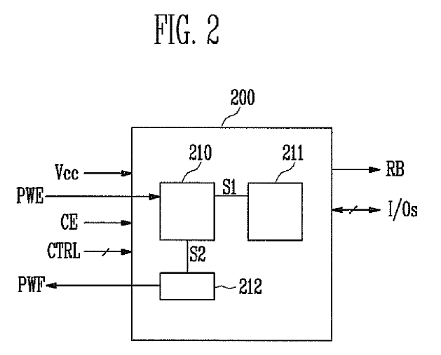

FIG. 2 is a block diagram illustrating any one of stack-type memory chips according to the present disclosure.

Referring to FIG. 2, the memory chip 200 includes a number of elements, including a memory cell. Further, I/O signals for operating the elements are transferred through at least one pin protruding outside of a semiconductor device. Some of the signals supplied to the memory chip 200 are described below.

The memory chip 200 is supplied with a power source voltage Vcc, a chip enable signal CE for selecting the memory chip 200, and a control signal CTRL. An operation signal RB indicating that the memory chip 200 is operating is outputted from the memory chip 200. Additionally, a number of the I/O signals I/Os may be inputted to or outputted from the memory chip 200.

The memory chip 200 includes a power-up operation unit 210, an internal circuit 211, and a power-up detection unit 212. The power-up operation unit 210 is configured to perform a power-up operation in response to a power-up enable signal PWE, and to output a powered-up control signal S1. The internal circuit 211 is configured to operate in response to the powered-up control signal S1. The power-up detection unit 212 is configured to output a power-up flag signal PWF in response to a power-up completion signal S2 outputted from the power-up operation unit 210 after the power-up operation is performed by the power-up operation unit 210.

The power-up operation unit 210 includes a power-up enable terminal to which the power-up enable signal PWE is inputted. The power-up operation unit 210 is configured to perform a power-up operation in response to the power-up enable signal PWE, and to output the powered-up control signal S1 to the internal circuit 211. After the power-up operation is completed, the power-up operation unit 210 outputs the power-up completion signal S2 to the power-up detection unit 212. The internal circuit 211 includes a memory cell array and a peripheral circuit unit, and operates in response to the powered-up control signal S1. The power-up detection unit 212 is configured to output the power-up flag signal PWF through a power-up flag terminal in response to the power-up completion signal 52.

In more detail, when the power-up enable signal PWE of a high logic level is received, the power-up operation unit 210 performs a power-up operation, and outputs the powered-up control signal S1 having a raised voltage level. Here, the power-up enable signal PWE may be supplied in synchronism with the power source voltage Vcc supplied to the memory chip 200, or may be supplied to the memory chip 200 through an individual external pin. After the power-up operation is completed, the voltage level of the powered-up control signal S1 is lowered. At this time, the power-up operation unit 210 outputs the power-up completion signal S2 of a high logic level. While the power-up operation is being performed, the power-up operation unit 210 preferably outputs the power-up completion signal S2 of a low logic level.

When the power-up completion signal S2 of a high logic level is received, the power-up detection unit 212 outputs the power-up flag signal PWF of a high logic level. As described above, the power-up detection unit 212 can detect the start, operation, and completion of a power-up operation, and output the power-up flag signal PWF according to each state. Thus, the power up detection unit 212 is capable of controlling the power-up operation of the memory chip 200.

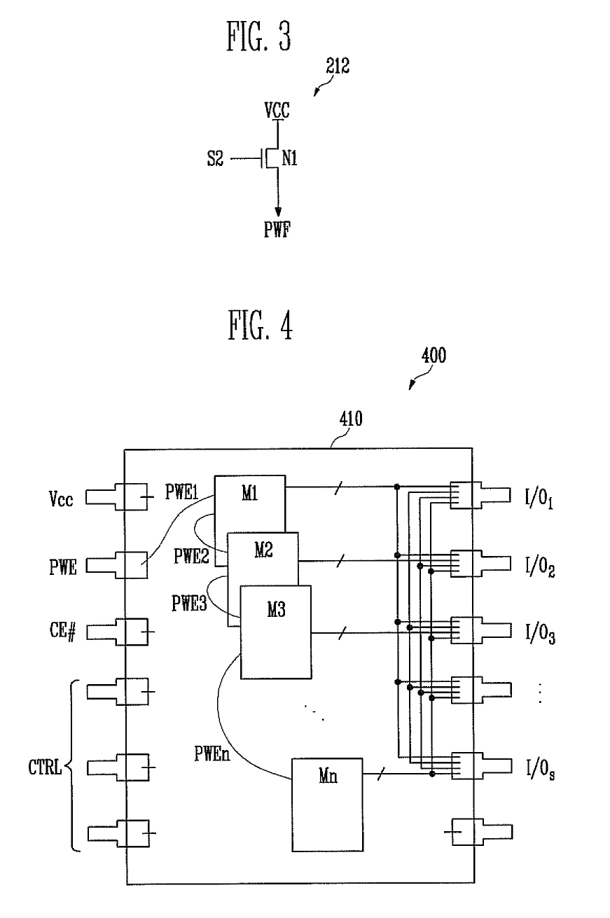

FIG. 3 is a circuit diagram of the power-up detection unit 212 included in the memory chip 200.

Referring to FIG. 3, after a power-up operation is completed, the power-up detection unit 212, as described above, outputs the power-up flag signal PWF of a high logic level. The power-up detection unit 212 can be constructed in various ways. Although, for the sake of convenience, only the exemplary power-up detection unit 212 shown in FIG. 3 is described below.

The power-up detection unit 212 can include a power-up detection element N1 coupled between a terminal to which the power source voltage Vcc is supplied and a terminal from which the power-up flag signal PWF is outputted. The power-up detection element N1 can be implemented using an NMOS transistor, and is configured to operate in response to the power-up completion signal S2. For example, when the power-up completion signal S2 of a high logic level is received, the power-up detection element N1 is turned on, and the power source voltage Vcc is transferred to the terminal for outputting the power-up flag signal PWF, so that the power-up flag signal PWF is activated.

FIG. 4 is a block diagram illustrating a semiconductor device including a package according to the present disclosure.

FIG. 4 schematically shows the semiconductor device 400 in which stack-type memory chips M1 to Mn (where ‘n’ is a natural number) are packaged in one chip. The semiconductor device 400 includes a package 410, including a number of the memory chips M1 to Mn, and a number of pins protruding outside of the package 410. The pins include a pin for a power source voltage Vcc, a chip enable pin CE#, control signal pins CTRL (e.g., ALE, CLE, and WE), and I/O pins I/O₁ to I/Oₛ.

In the case in which a number of the memory chips M1 to Mn are included in one package 410, a number of the pins are electrically coupled with the I/O terminals of the memory chips M1 to Mn through respective wires. A construction of an exemplary package 410 for use in a power-up operation is described below.

The I/O terminals of the memory chips M1 to Mn are electrically coupled to any one of a number of the pins protruding outside of the package 410.

For example, the package 410 can include a designated power-up enable pin PWE for a power-up operation. Alternatively, a single pin can be used for inputting both a power-up enable signal and the supply of a power source voltage. The power-up enable pin PWE may be electrically coupled with the power-up enable terminal of the first memory chip M1 through a corresponding wire. The memory chips M1 to Mn include respective power-up enable terminals, and the power-up flag terminals of neighboring memory chips are electrically coupled to each other using wires. These wires are not coupled to the pins of the package, but rather are internal wires (i.e., inside the package 410) coupled between the memory chips M1 to Mn. The power-up flag terminal outputs the power-up flag signal after the power-up operation of a corresponding memory chip is completed. The power-up operation within the package 410 is described in short below.

The first memory chip M1 is configured to perform a power-up operation in response to a first power-up enable signal PWE1. After the power-up operation is completed, the first memory chip M1 outputs a first power-up flag signal. The first power-up flag signal is supplied as a second power-up enable signal PWE2 supplied to a second memory chip M2. After the power-up operation of the second memory chip M2 is completed, the second memory chip M2 outputs a second power-up flag signal. The second power-up flag signal is supplied as a third power-up enable signal PWE3 supplied to a third memory chip M3. In the case in which a number of the memory chips M1 to Mn are included in one package 410, as described above, the corresponding power-up operations can be sequentially performed on a number of the memory chips M1 to Mn.

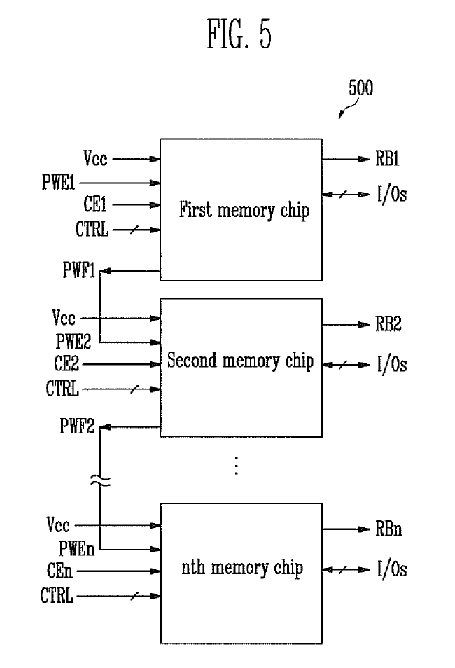

FIG. 5 is a block diagram illustrating a semiconductor device including stack-type memory chips according to the present disclosure.

FIG. 5 shows an example in which one semiconductor device 500 includes a number of the memory chips 200 shown in FIG. 2. For example, 2, 4, or memory chips can be stacked in one semiconductor device 500. In the case in which a number of the memory chips are stacked in one semiconductor device 500, power-up operations can be sequentially performed on the respective memory chips in response to the power-up enable signals PWE and the power-up flag signals PWF. That is, the power-up operation is first performed on a first memory chip, and after the power-up operation on the first memory chip is completed, the power-up operation is performed on a second memory chip. In this manner, a power-up operation is performed on each memory chip one at a time in an order from the first memory chip to the n^{th} memory chip. Thus, unselected memory chips do not perform the power-up operations until the power-up operations are completed for previous memory chips. This method of performing the power-up operations on each of the memory chips is accomplished by using the power-up flag signal PWF of the previous memory chip to indicate that the power-up operation has been completed in the previous memory chip. After the power-up operation on the selected memory chip is completed, any one of power-up flag signals PWF1 to PWFn (where ‘n’ is a natural number) is enabled by the selected memory chip, and any one of the power-up flag signals PWF1 to PWFn is supplied as any one of the power-up enable signals PWE1 to PWEn for a next memory chip. Thus, a memory chip enabled in response to any one of the power-up enable signals PWE1 to PWEn performs the power-up operation. The semiconductor device 500, including first to n^{th} memory chips (where ‘n’ is a natural number), is described in more detail below.

The first memory chip performs a power-up operation in response to the first power-up enable signal PWE1. The first power-up enable signal PWE1 can be supplied through a chip enable pin exposed outside of the semiconductor device 500, or can be supplied through the same pin as the power source voltage Vcc. In the case in which both the first power-up enable signal PWE1 and the power source voltage Vcc are supplied through the same pin, the power source voltage Vcc and the first power-up enable signal PWE1 are enabled (e.g., have a high level) at the same time, and so the power-up operation can be performed on the first memory chip. While the power-up operation is performed on the first memory chip, the first power-up flag signal PWF1 maintains an inactive state (e.g., has a low level). In particular, while the power-up operation is performed on the first memory chip, power-up operations are not performed on the remaining memory chips (i.e., the second to n^{th} memory chips) because the first power-up flag signal PWF1 and the second power-up enable signal PWE2 operate in conjunction with each other. After the power-up operation on the first memory chip is completed, the first power-up detection unit (not shown in FIG. 5, but shown as block 212 in FIG. 2) of the first memory chip enables/activates and outputs the first power-up flag signal PWF1.

When the first power-up flag signal PWF1 is enabled, the second power-up enable signal PWE2 operating in conjunction with the first power-up flag signal PWF1 is also activated. Accordingly, a power-up operation is performed on the second memory chip. In other words, after the power-up operation on the first memory chip is completed, the power-up operation on the second memory chip is performed. To this end, the first memory chip includes the first power-up detection unit 212, and the n^{th} memory chip (where ‘n’ is a natural number) can include the n^{th} power-up detection unit.

As described above, since the power-up operation unit and the power-up detection unit are included in each of memory chips, power-up operations can be sequentially performed on the memory chips. Accordingly, the power-up operations on the memory chips can be prevented from being performed at the same time. Consequently, excessive current can be prevented from flowing in a CAM cell configured to store bad block information, chip configuration information, and repair column information about memory chips. Furthermore, excessive current can also be prevented from being consumed in memory chips using a fuse, instead of the CAM cell. Consequently, a reduction in the lifespan of the semiconductor device can be suppressed, and the reliability of the semiconductor device can be improved.

What is claimed is:

1. A semiconductor device, comprising:
a power-up operation unit configured to perform a power-up operation in response to a power-up enable signal and to output a powered-up control signal, and configured to output a power-up completion signal after the power-up operation is completed;
an internal circuit configured to operate in response to the powered-up control signal; and
a power-up detection unit configured to output a power-up flag signal in response to the power-up completion signal.

2. The semiconductor device of claim 1, wherein the power-up operation unit comprises a terminal to which the power-up enable signal is supplied.

3. The semiconductor device of claim 2, wherein the terminal is electrically coupled through a wire to a pin receiving the power-up enable signal, protruding outside of the semiconductor device.

4. The semiconductor device of claim 1, wherein the power-up enable signal is supplied to the power-up operation unit through a pin to which a power source voltage is supplied.

5. The semiconductor device of claim 1, wherein the power-up operation unit is configured to:
perform the power-up operation in response to the power-up enable signal of a high logic level and to output the powered-up control signal, and
output the power-up completion signal of a high logic level when a voltage level of the powered-up control signal shifts to a low logic level after the power-up operation is completed.

6. The semiconductor device of claim 1, wherein the internal circuit comprises a memory cell array and a peripheral circuit unit.

7. The semiconductor device of claim 1, wherein the power-up detection unit comprises a power-up detection element coupled between a terminal to which a power source voltage is supplied and a terminal from which the power-up flag signal is outputted and configured to operate in response to the power-up completion signal.

8. The semiconductor device of claim 7, wherein the power-up detection element is implemented using an NMOS transistor.

9. A semiconductor device, comprising:
a number of memory chips;
a power-up operation unit included in each of the memory chips and configured to perform a power-up operation on an internal circuit included in each of the memory chips in response to a power-up enable signal; and
a power-up detection unit configured to output a power-up flag signal in response to a power-up completion signal outputted from the power-up operation unit,
wherein the power-up flag signal generated from the power-up detection unit of a first memory chip from among the memory chips is supplied as the power-up enable signal of a next memory chip from among the memory chips.

10. The semiconductor device of claim 9, wherein the power-up operation is sequentially performed in order from the first memory chip to a last memory chip from among the memory chips.

11. The semiconductor device of claim 9, further comprising wires configured to transfer the power-up flag signal outputted from each of the memory chips on which the power-up operation has been completed to the power-up enable signal of the next memory chip.

12. The semiconductor device of claim 11, wherein the wires comprise internal wires coupled between the memory chips, such that the wires are not coupled to pins of a package, including the memory chips.

13. The semiconductor device of claim 9, wherein an input terminal of the power-up operation unit included in the first memory chip from among the memory chips is coupled to a pin of a package, including the memory chips.

14. A semiconductor device, comprising:
a number of memory chips included in one package and coupled to pins of the package through wires;
a power-up operation unit included in each of the memory chips and configured to perform a power-up operation on an internal circuit included in each of the memory chips in response to a power-up enable signal; and
a power-up detection unit configured to output a power-up flag signal in response to a power-up completion signal outputted from the power-up operation unit,
wherein the power-up flag signal generated from the power-up detection unit of a first memory chip from among the memory chips is supplied as the power-up enable signal of a next memory chip from among the memory chips.

15. The semiconductor device of claim 14, wherein the power-up operation is sequentially performed in order from the first memory chip to a last memory chip from among the memory chips.

16. The semiconductor device of claim 14, further comprising wires configured to transfer the power-up flag signal outputted from each of the memory chips on which the power-up operation has been completed to the power-up enable signal of the next memory chip.

17. The semiconductor device of claim 16, wherein the wires comprise internal wires coupled between the memory chips, such that the wires are not coupled to the pins of the package.

18. The semiconductor device of claim 14, wherein an input terminal of the power-up operation unit included in the first memory chip from among the memory chips is coupled to one of the pins of the package.

19. A method of operating a semiconductor device comprising a number of memory chips, the method comprising:
performing a power-up operation on a first memory chip of the memory chips; and
performing the power-up operation on a next memory chip of the memory chips, after the power-up operation is completed,
wherein the power-up operation is sequentially performed up to a last memory chip of the memory chips.

20. The method of claim 19, wherein while the power-up operation is performed on a selected memory chip of the memory chips, the power-up operation is not performed on remaining memory chips other than the selected memory chip.
